(19) United States
(12) Patent Application Publication
(10) Pub. No.: US 2011/0232722 A1
(43) Pub. Date: Sep. 29, 2011

(54) HEAT TRANSFER ELEMENT AND ARRANGEMENT FOR COOLING SOLAR CELLS

(75) Inventor: Per Gunnar Eriksson, Vilhelmina (SE)

(73) Assignee: SUNCORE AB, Saltsjö-Boo (SE)

(21) Appl. No.: 13/121,621

(22) PCT Filed: Sep. 22, 2009
(86) PCT No.: PCT/SE2009/051052

§ 371 Date: Jun. 1, 2011

(30) Foreign Application Priority Data
Sep. 30, 2008 (SE) 0802067-9

(51) Int. Cl. H01L 31/052

(52) U.S. Cl. 136/246

(57) ABSTRACT

The invention relates to a heat transfer element and an arrangement using such an element to lower the temperature of solar cells. The heat transfer element is arranged to be placed on the shadow side of and in contact with a panel of solar cells and configured for collecting heat from the solar cells, said element comprising an inlet, an outlet and a internal passage extending between said inlet and said outlet and being arranged to guide a heat transporting fluid. Also the passage is defined between two generally parallel sheets. The arrangement comprises a heat transfer element arranged to be placed on the shadow side of and in contact with the panel and a system feeding a heat transporting fluid to said inlet and receiving the heat transporting fluid from said outlet. The invention also comprise an arrangement for cooling a panel of solar cells, comprising a heat transfer element arranged to be placed on the shadow side of and in contact with the panel and a system feeding a heat transporting fluid to said inlet of the element and receiving the heat transporting fluid from the outlet of said element.

### FIELD OF THE INVENTION

The present invention relates to a heat transfer element arranged to be placed on the shadow side of solar cells and configured for collecting heat from the solar cells, thereby lowering the temperature of the solar cells.

The present invention also comprises an arrangement for cooling solar cells, comprising a heat transfer element.

### BACKGROUND OF THE INVENTION

Photovoltaic (PV) is a technology field comprising solar cells for energy production by converting sunlight directly into electricity.

Due to the growing demand for solar energy, the manufacture of solar cells has expanded dramatically in recent years. According to some estimates the PV production of electricity has been doubling every two years, increasing by an average of 48 percent each year since 2002. At the end of 2007, according to preliminary data, cumulative global production was some 12,400 megawatts. Roughly 90% of this generating capacity consists of grid-tied electrical systems. Such installations may be ground-mounted or built into the roof or walls of a building, known as Building Integrated Photovoltaic or BIPV for short. Financial incentives, such as preferential feed-in tariffs for solar-generated electricity, and net metering, have supported solar PV installations in many countries.

High efficiency solar cells are solar cells specifically designed to generate electricity in a cost effective and efficient manner.

There are different types of solar cells having different properties. E.g. there are reports describing the highest efficiency for silicon solar cell as 24.7%, the highest efficiency for thin film based solar cells, CdTe, as 18% and for solar cells based on copper indium gallium selenide thin films, also known as CIGS, as 19.5%.

Tests made have also indicated that some solar cells show measurable decrease in their efficiency when their temperature rises above a certain level. Such a critical temperature level can be as low as 45° C. for some silicone based solar cells and is a temperature that is easily reached. A sunny day the temperature in a solar cell can reach well above 100° C. The solar cells are thus not performing as expected in bright sunlight. Our tests have shown that a silicone based solar cell with an efficiency of 17% was down and performing 3.4% when the temperature in the solar cell reached 80° C.

The term “panel of solar cells” is in this document used for one or more solar cells or modules or arrays of solar cells intended to make up a surface or surface unit to collect solar energy. Consequently, a panel of solar cells can comprise solar cells mounted on a substrate of any kind or just being by them self's or being of a thin film type or any other type making up an area for collecting and transforming solar energy to electricity. One solar cell is usually small having small electrical output and is therefore often connected with others to reach desired peak voltage and current.

Attempts have been made to lower the temperature in the solar cells to increase the efficiency by causing air to blow past the cells to carry off heat. This convection approach of carry of heat has proven insufficient in some applications and weather conditions.

One other approach has been explored for silicone based solar cells, to use as pure a silicone as possible. By reducing the content of heat absorbing dark contaminations in the solar cells, it is possible to reduce, to some extent, the relative working temperature for a pure silicone solar cell compared to a traditional. However, when the critical temperature is reached, the efficiency rapidly decreases, even tough the critical temperature is a few degrees higher. It also raises the price on the solar cells and reduces the volumes that can be produced.

### OBJECT AND SUMMARY OF THE INVENTION

It is therefore an object of the present invention to provide a heat transfer element and an arrangement that solves or at least alleviates to some extent the abovementioned challenges. These objects are achieved by the present invention as it is defined in the attached independent claims.

A heat transfer element, arranged to be placed on the shadow side of and in contact with a panel of solar cells, is configured for collecting heat from the solar cells and thereby lowering the temperature in the solar cells. Said element comprises an inlet, an outlet and an internal passage extending between said inlet and said outlet. Said passage is defined between two generally parallel sheets and is arranged to guide a heat transporting fluid. In this way heat can be transported away from the solar cells using conduction, which is an effective way to transport heat.

In one embodiment, at least one of said sheets is of a non-conductive material. Herewith the risk of short circuiting the solar cells can be avoided.

In one embodiment, said material can be a polymer. Polymers are available having a verity of properties that can be adapted and designed to specific situations and shapes, with regard to e.g. working temperatures, temperature fluctuation, UV resistance, resistance to impact, resistivity, etc.

In another embodiment said element can be self-supporting. Hereby the element keeps its intended form, is easy to position and can also be used as part of a structure.

In another embodiment one sheet can have a pattern that configures the passage and the other sheet can be plane. Hereby the plane sheet can be placed against the shadow side of a panel of solar cells or the plane side can act as a substrate on which solar cells are mounted to maximize the contact surface between the element and the solar cells.

In one embodiment, the sheets can be bound to each other by means of material homogeneous joints. In one other embodiment, the sheets can be bound to each other with joints having the same molecular structure as the sheets. Also the joints between the sheets can have the same material thickness as the sheets. Having as homogenous a material as possible improves the durability in elements exposed to high and frequent temperature variations.

In further embodiments, the polymer material can be from a group of plastic materials comprising e.g. ABS-plastics, polycarbonate plastics, polypropene, etc.

In still further embodiments, the sheets can comprise layers building up the properties of the sheets. Hereby the element properties can be specially designed and adapted for different situations.

In still another embodiment, a plurality of spot joints can be arranged between the sheets and distributed over the passage area, preferably in combination with dimples arranged in one of the plates. Such spot joints add to the elements rigidity and increase its strength and possible use as a part of a structure. It also helps forming the internal passage and strengthens its form stability. For example, when a fluid in the internal passage gets pressurized, the sheets show a tendency to separate and make the passage higher. In such a case the spot joints help keep the sheets at a predefined distance, therewith ensuring that the thickness of the fluid in the passage is not increasing.

In one embodiment the solar cells can be placed on a glass substrate and the element is abutting that substrate. It is positive to have a substrate that shows good thermal conductivity.

In one embodiment the solar cells can be placed directly on a plane sheet of the element, whereas said sheet can act as a substrate for solar cells.

The present invention further comprise an arrangement for cooling a panel of solar cells, comprising a heat transfer element arranged to be placed on the shadow side of and in contact with the panel, said element comprising an inlet, an outlet and an internal passage extending between said inlet and said outlet, and a system feeding a heat transporting fluid to said inlet and receiving the heat transporting fluid from the outlet. Hereby the temperature in the solar cells can be lowered by carrying off heat.

In one embodiment said system can further comprise means for collecting and carry of heat from the heat transporting fluid received from said outlet before again feeding it to said inlet. Hereby the heat energy can be used for other purposes, e.g. heating water.

The present invention will be explained in more detail hereinafter on the basis of a detailed description of some embodiments of the invention, which embodiments are meant solely to be examples. In the following description, reference is made to the appended figures, in which:

### BRIEF DESCRIPTION OF THE DRAWINGS

FIG. 1 schematically shows an exploded side view of a heat transport element according to the principles in one embodiment of the present invention and a panel of solar cells.

FIG. 2 schematically shows the principles of the arrangement according to FIG. 2 in a active position.

FIG. 3 schematically shows the patterned side of the element according to FIGS. 1 and 2.

FIG. 4 schematically shows an embodiment arrangement for cooling a panel of solar cells.

### DETAILED DESCRIPTION OF EMBODIMENTS

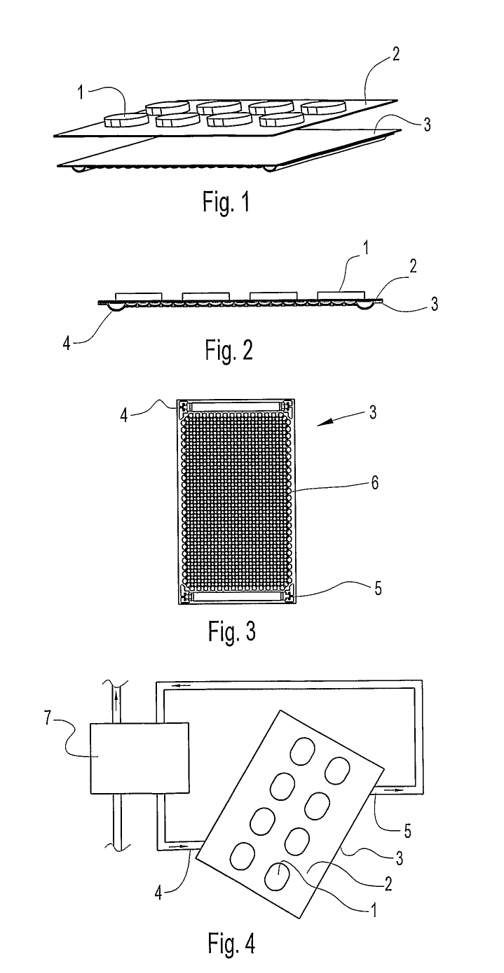

With reference to FIGS. 1 and 2, in a first embodiment of the present invention a number of silicone based solar cells 1 are placed on a substrate 2 or carrier of glass forming a panel of solar cells. Below the substrate is a heat transfer element 3 arranged with a plane surface abutting the underside of the glass. Here the outer outline of the substrate and the outer outline of the element is generally the same to secure a maximum contact area between them for good heat conduction.

The heat transfer element comprises an inlet channel 4, an outlet channel 5 and an internal passage 6 connecting the inlet and the outlet. In this embodiment the element is produced from two sheets of an ABS plastic material, showing a carbon content that is sufficiently low and a resistance against absorbing moisture to ensure a non-conductive material. The first sheet is a plane rectangular sheet and the second sheet is a rectangular sheet provided with topographic patterns creating the inlet channel 4, the outlet channel 5 and the passage 6.

The inlet 4 and the outlet 5 respectively, show in the present embodiment a through passage making it possible to arrange a number of heat transfer elements side by side in a larger system if desired. Otherwise, the through passage of the inlet and outlet respectively can be plugged up. However, the inlet channel makes it possible to feed a heat transporting fluid over the entire inlet side of the internal passage. Likewise, the outlet channel makes it possible to receive the heat transporting fluid over the entire outlet side of the internal passage, hereby making the transport of heat efficient.

The pattern in the second sheet is the result of a plastic deformation of the second sheet before or in joint operation with a sealing operation between the two sheets. The sealing operation is performed around the edges of the first sheet and the second sheet and with a plurality of spot joints between the two sheets distributed over the passage area 6 and in combination with dimples formed in the second sheet. The thus formed web like pattern of passage channels runs between the inlet and the outlet ensures that a large wet surface is reached and that the two sheets will not separate when a fluid in the element gets pressurised. Also the efficiency of the element can be fine-tuned and adapted to different working conditions by adapting the distance between the sheets in the passage, thus the height of the fluid intended to flow through the passage.

Further, with reference to FIG. 4, the heat transfer element 3 arranged in contact with the panel of solar cells 1, 2 is connected to a system feeding a heat transporting fluid to said inlet 4 and receiving the heat transporting fluid from the outlet 5. The system further comprises a counter flow heat exchanger 7 to utilize the heat for other purposes, e.g. heating water.

In other embodiments, the heat transporting fluid can be made to just pass the element ones, not circulate, or the circulation can be made to pass a cooling arrangement before in again is introduced at the inlet.

Using a ABS material to the sheets when forming the heat transport element provides some favourable features. It is possible to produce joints of high quality, in respect of impact strength, durability and leaks. The spot joints increase the already form stable sheets, so that the element gets self-supporting to a degree where it also can be used as a part in a structure but still allow for some minor flexing.

In another embodiment, the solar cells are arranged in a foil or in some other type accepting minor flexing in a substrate or carrier and there is no need for the glass substrate between the solar cell and the element. Thus the solar cells can be placed directly on the plane side of the heat transfer element, even if the material in the sheets is a plastic material, such as e.g. ABS.

In another embodiment, the inlet and the outlet each can comprise a connector arrangement in the form of a quick coupling for tool free connection of a pipe, tube or hose. In the embodiment with inlet and outlet channels, the connector arrangement can of course be placed in both ends of said channels.

The quick coupling comprises a housing arranged in an opening in the inlet or the outlet. The housing is preferably manufactured in the same material as the sheets and sealed to the sheets in the same manner as the sheets are sealed to each other. They can also be attached by welding, adhesives or other suitable means. In the housing is arranged a cylindrical aperture with a countersunk collar, a sealing device in the form of a O-ring arranged to be asserted against said countersunk collar, a plane washer asserted against the O-ring, a pipe/tube/hose gripping means in the form of a ring with internal barbs asserting the plane washer and a locking means realisably holding the gripping means in position. Hereby the element can easily be connected to a system for a heat transporting fluid. Such fluids are well known for the person skilled in the art and will therefore not be further explained.

Examples of a non-conductive material can in applications like this e.g. have a resistivity above 1×10⁶ Ωm, preferably above 1×10⁸ Ωm, more preferably above 1×10¹⁰Ωm and most preferably above 1×10¹³ Ωm.

In the claims, any reference signs placed between parentheses shall not be constructed as limiting the claim. The word “comprising” does not exclude the presence of elements or steps other than those listed in a claim. The word “a” or “an” preceding an element does not exclude the presence of a plurality of such elements.

1. Heat transfer element arranged to be placed on the shadow side of and in contact with a panel of solar cells and configured for collecting heat from the solar cells thereby lowering the temperature of the solar cells, said element comprising an inlet, an outlet and a internal passage extending between said inlet and said outlet and being arranged to guide a heat transporting fluid, said passage being defined between two generally parallel sheets, whereas a plurality of spot joints between the sheets are distributed over the passage area, preferably in combination with dimples arranged in at least one of the plates.

2. Heat transfer element according to claim 1, whereas at least one of said sheets is of a non-conductive material.

3. Heat transfer element according to claim 2, whereas said material is a polymer.

4. Heat transfer element according to claim 1, whereas one sheet shows a pattern configuring the passage pattern and the other plate is plane.

5. Heat transfer element according to claim 4, whereas said plane sheet is arranged to abut the panel of solar cells.

6. Heat transfer element according to claim 1, whereas the sheets are bound to each other by means of material homogeneous joints.

7. Heat transfer element according to claim 1, whereas the sheets are bound to each other with joints having the same molecular structure as the sheets.

8. Heat transfer element according to claim 1, whereas the joints between the sheets have the same material thickness as the sheets.

9. Heat transfer element according to claim 1, whereas the polymer material is a plastic material selected from the group consisting of ABS, polycarbonate plastics, and polypropene.

10. Heat transfer element according to claim 1, whereas the solar cells are placed on a glass substrate and the element is abutting that substrate.

11. Heat transfer element according to claim 3, whereas the solar cells are placed directly on one said elements sheets, said sheet thus acting as substrate.

12. Arrangement for cooling a panel of solar cells, comprising a heat transfer element arranged to be placed on the shadow side of and in contact with the panel, said element comprising an inlet, an outlet and an internal passage extending between said inlet and said outlet, and a system feeding a heat transporting fluid to said inlet and receiving the heat transporting fluid from the outlet, whereas a plurality of spot joints between the sheets are distributed over the passage area, preferably in combination with dimples arranged in at least one of the plates.

13. Arrangement according to claim 12, whereas said system further comprise means for collecting the heat from the heat transporting fluid received from said outlet before again feeding it to said inlet.
